(19) United States
(12) Patent Application Publication
(10) Pub. No.: US 2025/0324624 A1
(43) Pub. Date: Oct. 16, 2025

(54) RESISTOR STRUCTURE WITH CAPPING STRUCTURE ON TFR LAYER

(71) Applicant: Taiwan Semiconductor Manufacturing Company, Ltd., Hsinchu (TW)

(72) Inventors: Chun-Tsung Kuo, Tainan City (TW); Hung-Wen Hsu, Tainan City (TW); Jiech-Fun Lu, Madou Township (TW)

(21) Appl. No.: 19/250,139

(22) Filed: Jun. 26, 2025

Related U.S. Application Data
(63) Continuation of application No. 18/407,705, filed on Jan. 9, 2024.
(60) Provisional application No. 63/520,671, filed on Aug. 21, 2023.

(51) Int. Cl. H10D 1/47; H01L 23/522; H01L 23/528; H10D 84/00

(52) U.S. Cl. CPC H10D 1/47; H01L 23/5226; H01L 23/5283; H10D 84/209

(57) ABSTRACT

Various embodiments of the present disclosure are directed towards an integrated chip including a thin film resistor (TFR) layer overlying a semiconductor substrate. A first conductive structure is disposed on an outer region of the TFR layer. The first conductive structure comprises a lateral portion adjacent to a vertical portion. A height of the vertical portion is greater than a height of the lateral portion. A capping structure is disposed on a middle region of the TFR layer and abuts the vertical portion of the first conductive structure.

### REFERENCE TO RELATED APPLICATIONS

This application is a Continuation of U.S. application Ser. No. 18/407,705, filed on Jan. 9, 2024, which claims the benefit of U.S. Provisional Application No. 63/520,671, filed on Aug. 21, 2023. The contents of the above-referenced Patent Applications are hereby incorporated by reference in their entirety.

### BACKGROUND

Modern integrated chips use a wide range of devices to achieve varying functionalities. In general, integrated chips comprise active devices and passive devices. Active devices include transistors (e.g., metal-oxide-semiconductor field-effect transistor (MOSFETs)), while passive devices include inductors, capacitors, and resistors. Resistors are widely used in many applications such as resistor-capacitor (RC) circuits, power drivers, power amplifiers, radio frequency (RF) applications, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip including a resistor structure comprising a capping structure overlying a thin film resistor (TFR) layer.

FIG. 2 illustrates a cross-sectional view of some embodiments of an integrated chip having a resistor structure disposed within an interconnect structure.

FIG. 3 illustrates a top view of some embodiments of the resistor structure taken along the line A-A′.

FIGS. 4A-4D illustrate cross-sectional views of some other embodiments of the integrated chip of FIG. 2.

FIGS. 5A-5B through 13A-13B illustrate various views of some embodiments of a method for forming an integrated chip having a resistor structure including a capping structure overlying a TFR layer.

FIG. 14 illustrates a flow chart of some embodiments of a method for forming an integrated chip having a resistor structure including a capping structure overlying a TFR layer.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some integrated chips have passive devices disposed over/within a semiconductor substrate. The passive devices may, for example, include inductors, resistors, capacitors, diodes, etc. One type of resistor used in an integrated chip is a thin film resistor (TFR) disposed over the semiconductor substrate. The TFR comprises a TFR layer (e.g., a resistive layer) and a pair of conductive structures. The TFR layer comprises a middle region continuously extending between a pair of outer regions. The conductive structures directly over a corresponding outer region of the TFR layer, where the middle region of the TFR layer continuously extends between the conductive structures. A resistance of the TFR layer is based on a material and a thickness of the TFR layer.

A method for forming a plurality of TFRs over a semiconductor substrate (e.g., a semiconductor wafer) includes depositing a TFR film on a lower dielectric layer that overlies the semiconductor substrate. A conductive layer is deposited on the TFR film. A first dry etch is performed on the TFR film and the conductive layer to define a plurality of TFR layers for corresponding TFRs over the semiconductor substrate. Each TFR layer comprises a middle region continuously extending between a pair of outer regions. A second dry etch is performed on the conductive layer to reduce a thickness of the conductive layer over each middle region of the TFR layers. Subsequently, a wet etch process is performed on the conductive layer to remove portions of the conductive layer from over each middle region of the TFR layers. This forms a pair of conductive structures over the outer regions of each TFR layer. During the wet etch process the semiconductor substrate is dipped in and/or exposed to a wet etchant (e.g., hydrogen peroxide) utilized to remove the portions of the conductive layer. The wet etchant comes in contact with and damages and/or reduces a thickness of portions of the TFR layers (e.g., the middle region of each TFR layer). This may result in each of the TFR layers having a higher total thickness variation (TTV) and/or a non-uniform thickness, thereby reducing a performance or reliability of the TFRs (e.g., due to damage to the TFR layers from the wet etchant). For example, the non-uniform thickness may cause sheet resistance variation across different regions of the TFR layers (e.g., along the middle region of the TFR layers) such that an overall performance of the TFRs is reduced and/or the TFRs do not meet design specifications (e.g., the TFRs have a resistance that do not fall within the design specifications).

Further, due to a method of applying the wet etchant and an etching rate of the TFR layer during the wet etch process, the wet etchant does not uniformly reduce the thickness of the TFR layers across the semiconductor substrate. As a result, a first thickness of the TFR layer in a center region of the semiconductor substrate is substantially different from a second thickness of the TFR layer in a peripheral region of the semiconductor substrate. This results in the TFRs having a relatively high variation of resistance across the semiconductor substrate. The variation of resistance of the TFRs reduces a performance of the integrated chip and/or may result in failing a wafer acceptance test (WAT), thereby reducing device yield.

Accordingly, the present disclosure is directed towards an integrated chip comprising a resistor structure having a TFR layer and a corresponding method of fabrication configured to reduce a thickness variation of the TFR layer. The TFR layer overlies a semiconductor substrate comprises a middle region continuously extending between a pair of outer regions. A pair of conductive structures overlie the pair of outer regions of the TFR layer. A capping structure overlies the middle region of the TFR layer and continuously extends between the pair of conductive structures. During fabrication of the resistor structure, the capping structure is disposed on the TFR layer while a wet etch process is performed on a conductive layer to form and/or define the conductive structures. The capping structure is configured to protect the TFR layer from a wet etchant (e.g., hydrogen peroxide) utilized during the wet etch process. As a result, removal of and/or damage to the TFR layer during the wet etch process is minimized such that the TFR layer has a uniform thickness, decreased TTV, and increased reliability. Further, this mitigates a non-uniform removal of TFR layers across the semiconductor substrate, thereby increasing a uniformity of resistance of resistor structures across the semiconductor substrate. As a result, an overall performance of the integrated chip and a device yield are increased.

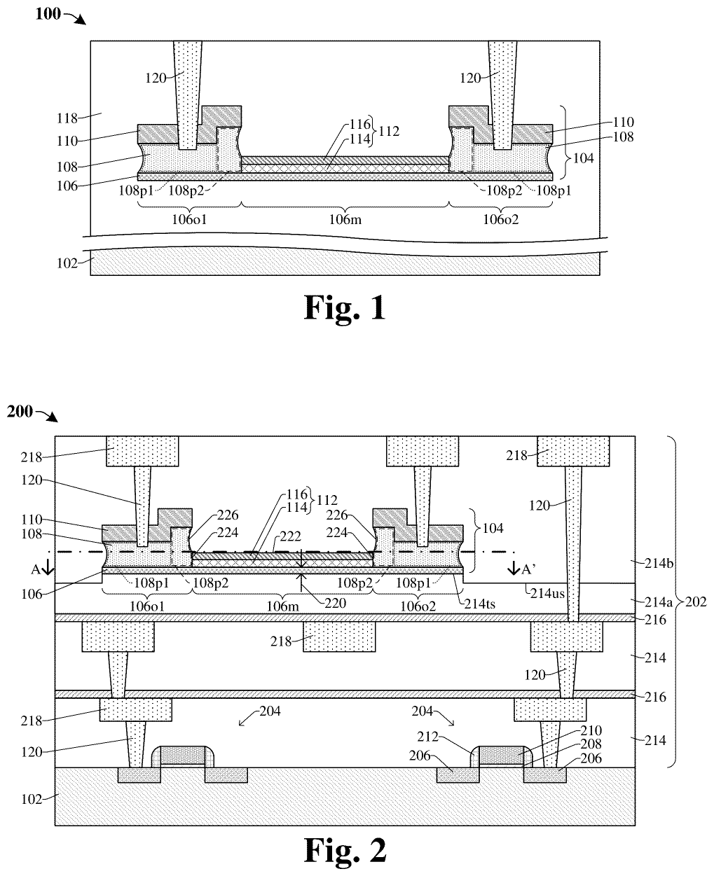

FIG. 1 illustrates a cross-sectional view 100 of some embodiments of an integrated chip including a resistor structure 104 comprising a capping structure 112 overlying a thin film resistor (TFR) layer 106.

The integrated chip comprises a dielectric structure 118 overlying a semiconductor substrate 102. The resistor structure 104 is disposed within the dielectric structure 118. A plurality of conductive vias 120 are disposed within the dielectric structure 118 and overlie the resistor structure 104. The conductive vias 120 are electrically coupled to the resistor structure 104.

The resistor structure 104 comprises the TFR layer 106, a pair of conductive structures 108 disposed on the TFR layer 106, and the capping structure 112 on the TFR layer 106. In some embodiments, the capping structure 112 and the conductive structures 108 directly contact a top surface of the TFR layer 106. An etch stop layer 110 overlies the conductive structures 108. The TFR layer 106 may, for example, be or comprise silicon chromium, nickel chromium, or the like. Other materials for the TFR layer 106 are, however, amenable. The conductive structures 108 are configured to electrically couple the TFR layer 106 to the plurality of conductive vias 120. The resistor structure 104 is configured to resist (e.g., reduce) current flow between the conductive structures 108. A resistance of the resistor structure 104 is based, at least in part, on a material and a thickness of the TFR layer 106. In some embodiments, the resistor structure 104 may, for example, be used in resistor-capacitor (RC) circuits, power drivers, power amplifiers, RF applications, analog-to-digital converters (ADCs), digital-to-analog converters (DACs), other suitable electronic devices, or any combination of the foregoing.

The TFR layer 106 comprises a middle region 106m continuously extending between a pair of outer regions 10601, 10602. The conductive structures 108 directly overlie the outer regions 10601, 10602 of the TFR layer 106. The capping structure 112 directly overlies the middle region 106m of the TFR layer 106 and continuously laterally extends between the pair of conductive structures 108. In some embodiments, the capping structure 112 directly contacts the conductive structures 108. The conductive structures 108 respectively comprise a first portion 108p1 adjacent to a second portion 108p2, where a height of the first portion 108p1 is less than a height of the second portion 108p2. In various embodiments, the capping structure 112 comprises a first capping layer 114 disposed on the TFR layer 106 and a second capping layer 116 overlying the first capping layer 114.

Because the capping structure 112 directly overlies the middle region 106m of the TFR layer 106, the thickness of the TFR layer 106 may be maintained during fabrication of the resistor structure 104 and/or a total thickness variation (TTV) of the TFR layer 106 may be reduced. For example, during fabrication of the resistor structure 104, the capping structure 112 is disposed on the TFR layer 106 while an etch process (e.g., a wet etch process) is performed on a conductive layer to form and/or define the conductive structures 108. The capping structure 112 is configured to protect the TFR layer 106 from an etchant (e.g., hydrogen peroxide) utilized during the etch process. As a result, removal of the TFR layer 106 during the etch process is prevented and/or mitigated such that the thickness of the TFR layer 106 is maintained during and/or after the etch process. This decreases the TTV of the TFR layer 106 and facilitates the resistor structure 104 having a predefined resistance that meets design specifications. Further, the capping structure 112 prevents damage to the TFR layer 106 during the etch process, thereby increasing a reliability of the TFR layer 106.

Further, the presence of other capping structures (not shown) over other TFR layers (not shown) across the semiconductor substrate 102 mitigates a non-uniform reduction of thicknesses of the other TFR layers across the semiconductor substrate 102 during the etch process. As a result, a uniformity of resistance of resistors structures across the semiconductor substrate 102 is increased. This mitigates the chances that the integrated chip may fail a WAT and increases a device yield.

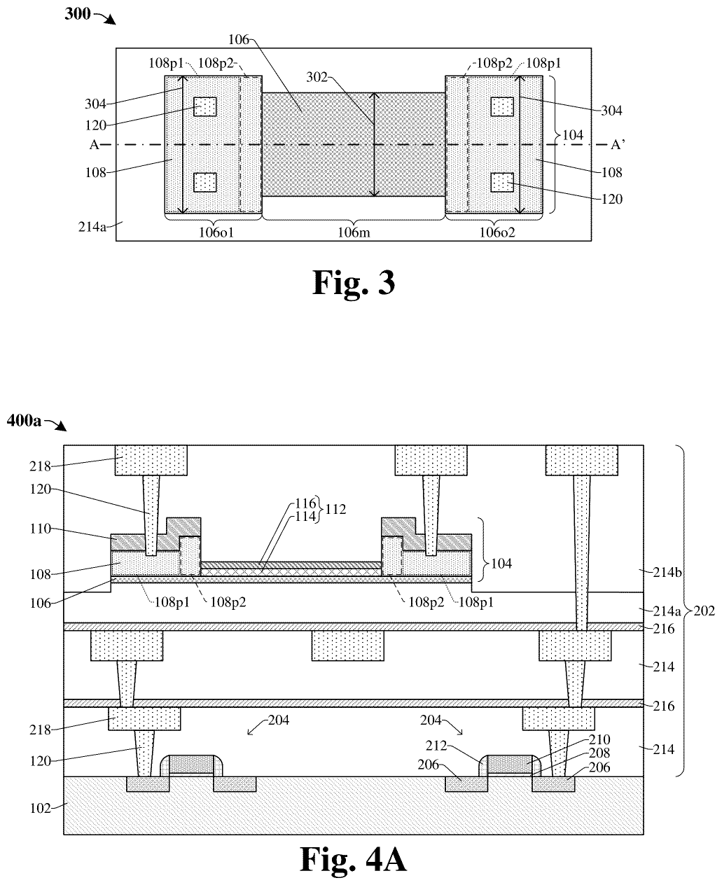

FIG. 2 illustrates a cross-sectional view 200 of some embodiments of an integrated chip that includes a resistor structure 104 disposed within an interconnect structure 202. In some embodiments, the resistor structure 104 is configured as illustrated and/or described in FIG. 1.

The interconnect structure 202 overlies a semiconductor substrate 102. The semiconductor substrate 102 may, for example, be or comprise silicon, germanium, silicon germanium, a bulk silicon substrate, one or more epitaxial layers, a silicon-on-insulator (SOI) substrate, or another suitable substrate material. The interconnect structure 202 comprises a plurality of conductive vias 120 and a plurality of conductive wires 218 disposed within a dielectric structure. The dielectric structure comprises a plurality of dielectric layers 214 and a plurality of dielectric protection layers 216. The plurality of conductive vias 120 and the plurality of conductive wires 218 are configured to electrically couple devices disposed within and/or over the semiconductor substrate 102 to one another. The plurality of dielectric layers 214 include a first dielectric layer 214a and a second dielectric layer 214b disposed over the first dielectric layer 214a.

The plurality of dielectric layers 214 may, for example, be or comprise silicon dioxide, a low-k dielectric material such as undoped silica glass, carbon-doped silicon dioxide, some other suitable dielectric material, or any combination of the foregoing. The plurality of dielectric protection layers 216 may, for example, be or comprise silicon carbide, silicon nitride, or the like. The conductive vias and wires 120, 218 may, for example, be or comprise copper, aluminum, titanium nitride, tantalum nitride, ruthenium, another conductive material, or any combination of the foregoing.

A plurality of semiconductor devices 204 are disposed within and/or on the semiconductor substrate 102. In some embodiments, the semiconductor devices 204 are configured as transistors. In such embodiments, the semiconductor devices 204 each comprise source/drain regions 206, a gate dielectric layer 208, a gate electrode 210, and a sidewall spacer structure 212. The gate electrode 210 overlies the gate dielectric layer 208 and the source/drain regions 206 are disposed within the semiconductor substrate 102 on opposing sides of the gate electrode 210. Source/drain region(s) may refer to a source or a drain, individually or collectively dependent upon the context.

The resistor structure 104 is disposed over the first dielectric layer 214a. The resistor structure 104 comprises a TFR layer 106, a pair of conductive structures 108 disposed on opposing sides of the TFR layer 106, and a capping structure 112 on the TFR layer 106 between the pair of conductive structures 108. The first dielectric layer 214a comprises a top surface 214ts disposed above an upper surface 214us. In some embodiments, a bottom surface of the TFR layer 106 directly contacts the top surface 214ts of the first dielectric layer 214a and outer sidewalls of the TFR layer 106 are aligned with opposing sidewalls of the first dielectric layer 214a. The capping structure 112 overlies and directly contacts a middle region 106m of the TFR layer 106. The conductive structures 108 overlie and directly contact outer regions 10601, 10602 of the TFR layer 106. In some embodiments, a thickness 220 of the TFR layer 106 is within a range of about 40 to 70 angstroms or some other suitable value. The conductive structures 108 may, for example, be or comprise titanium nitride, tantalum nitride, titanium, tantalum, some other conductive material, or any combination of the foregoing. In some embodiments, thicknesses of the conductive structures 108 may, for example, be within a range of about 500 to 1,000 angstroms.

The conductive structures 108 respectively comprise a first portion 108p1 adjacent to a second portion 108p2. In some embodiments, a height of the first portion 108p1 is less than a height of the second portion 108p2. The capping structure 112 continuously extends between the second portion 108p2 of a first conductive structure in the conductive structures 108 to the second portion 108p2 of a second conductive structure in the conductive structures 108. In various embodiments, the first portion 108p1 comprises a sidewall that is curved and the second portion 108p2 comprises a sidewall having a curved segment 226 over a straight segment 224. In some embodiments, a height of the curved segment 226 is greater than a height of the straight segment 224. In further embodiments, the height of the straight segment 224 is equal to a height of the capping structure 112. In yet further embodiments, the height of the curved segment 226 is equal to or greater than a height of the curved sidewall of the first portion 108p1. Further, a length of the first portion 108p1 is greater than a length of the second portion 108p2. In further embodiments, heights of the conductive structures 108 discretely increase from a corresponding outer sidewall of the TFR layer 106 in a direction towards the middle region 106m.

An etch stop layer 110 is disposed over the conductive structures 108. In some embodiments, the etch stop layer 110 continuously extends from a top surface of the first portion 108p1 along a sidewall of the second portion 108p2 to a top surface of the second portion 108p2. The etch stop layer 110 may, for example, be or comprise silicon nitride, silicon carbide, silicon oxynitride, or the like. In some embodiments, a thickness of the etch stop layer 110 is within a range of about 300 to 500 angstroms or some other suitable value. In further embodiments, the thickness of the etch stop layer 110 is less than the thicknesses of the conductive structures 108.

The capping structure 112 directly overlies the middle region 106m of the TFR layer 106. In some embodiments, the capping structure 112 comprises a first capping layer 114 on the TFR layer 106 and a second capping layer 116 on the first capping layer 114. In various embodiments, outer sidewalls of the first capping layer 114 are aligned with outer sidewalls of the second capping layer 116. The capping structure 112 is configured to prevent damage to the TFR layer 106 during fabrication of the resistor structure 104. For example, the capping structure 112 is formed before the conductive structures 108 and is configured to protect the TFR layer 106 during an etch process utilized to from and/or define the conductive structures 108. As a result, damage to and/or a non-uniform removal of a portion (e.g., the middle region 106m) of the TFR layer 106 during fabrication is mitigated. This, in part, decreases a TTV of the TFR layer 106 and/or decreases damage (e.g., delamination) to the TFR layer 106, thereby increasing reliability and an overall performance of the resistor structure 104. Further, by virtue of other capping structures (not shown) being disposed over other TFR layers (not shown) across the semiconductor substrate 102, a non-uniform reduction of the other TFR layers during fabrication is decreased. Accordingly, a uniformity of resistance of resistor structures across the semiconductor substrate 102 is increased, thereby increasing device yield of the integrated chip.

The first capping layer 114 may, for example, be or comprise an oxide such as silicon dioxide or some other suitable dielectric material. In various embodiments, a thickness of the first capping layer 114 is within a range of about 100 to 200 angstroms or some other suitable value. The second capping layer 116 may, for example, be or comprise silicon nitride, silicon carbide, some other suitable dielectric material, or any combination of the foregoing. In various embodiments, a thickness of the second capping layer 116 is within a range of about 100 to 200 angstroms or some other suitable value. In some embodiments, the thickness of the first capping layer 114 is equal to the thickness of the second capping layer 116. In further embodiments, thicknesses of the first and second capping layers 114, 116 are respectively greater than the thickness of the TFR layer 106. In yet further embodiments, the capping structure 112 directly contacts an entirety of the top surface of the middle region 106m of the TFR layer 106. In various embodiments, a lower surface 222 of the second dielectric layer 214b is vertically spaced from the top surface of the TFR layer 106 by the capping structure 112.

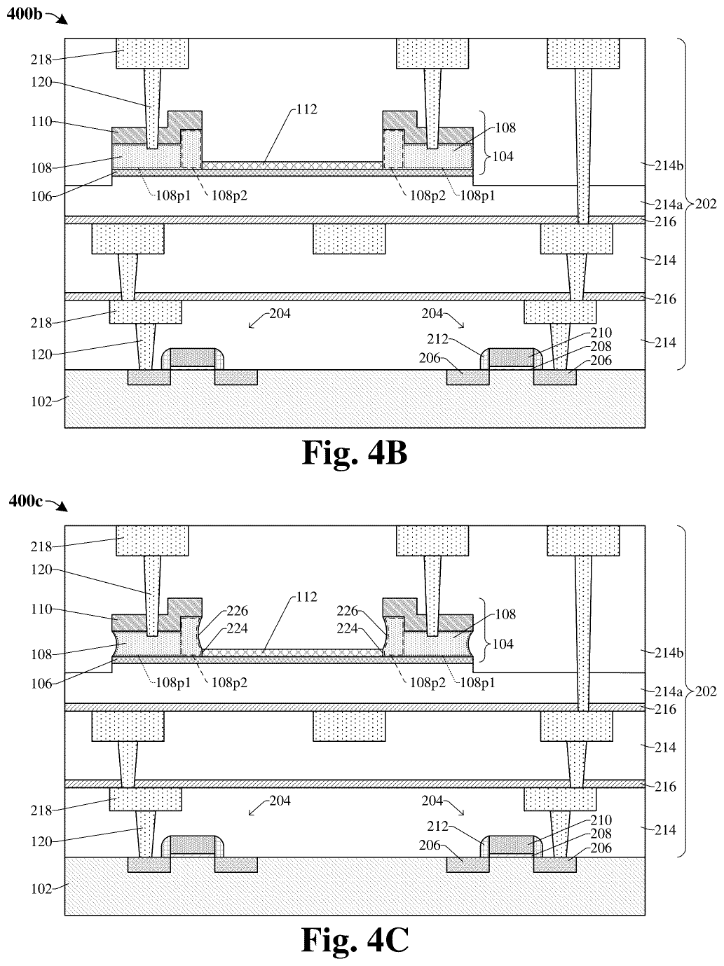

FIG. 3 illustrates a top view 300 of some embodiments of the cross-sectional view 200 of FIG. 2 taken along line A-A′.

As illustrated in FIG. 3, a width 302 of the middle region 106m of the TFR layer 106 is less than a width 304 of the outer regions 10601, 10602 of the TFR layer 106. In various embodiments, a width of the capping structure (112 of FIG. 2) is equal to the width 302 of the middle region 106m. In further embodiments, a width of the conductive structures 108 is equal to the width 304 of the outer regions 10601, 10602.

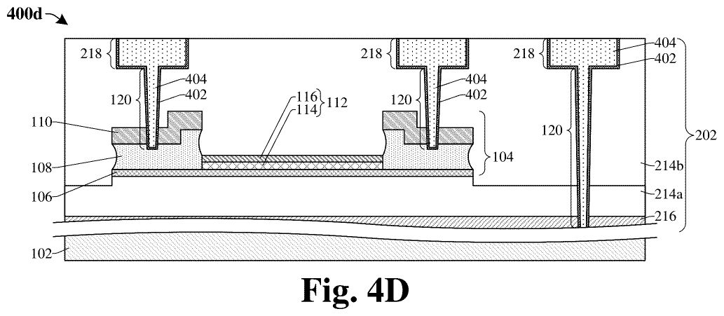

FIG. 4A illustrates a cross-sectional view 400a of some embodiments of an integrated chip corresponding to other embodiments of the integrated chip of FIG. 2, in which sidewalls of the first and second portions 108p1, 108p2 are straight. In some embodiments, an individual sidewall in opposing sidewalls of each of the conductive structures 108 is aligned with a corresponding outer sidewall of the TFR layer 106.

FIG. 4B illustrates a cross-sectional view 400b of some embodiments of an integrated chip corresponding to other embodiments of the integrated chip of FIG. 4A, in which the second capping layer (116 of FIG. 4A) is omitted. In some embodiments, the capping structure 112 comprises a single dielectric layer (e.g., the first capping layer 114 of FIG. 4A).

FIG. 4C illustrates a cross-sectional view 400c of some embodiments of an integrated chip corresponding to other embodiments of the integrated chip of FIG. 4A, in which the second capping layer (116 of FIG. 4A) is omitted and the second portion 108p2 of the conductive structures 108 comprises a sidewall having a curved segment 226 over a straight segment 224. In some embodiments, the capping structure 112 comprises a single dielectric layer (e.g., the first capping layer 114 of FIG. 4A). In some embodiments, a height of the straight segment 224 is equal to a height of the capping structure 112.

FIG. 4D illustrates a cross-sectional view 400d of some embodiments of an integrated chip corresponding to other embodiments of the integrated chip of FIG. 4A, in which the plurality of conductive vias 120 and the plurality of conductive wires 218 respectively comprise a conductive body 404 and a diffusion barrier layer 402. The diffusion barrier layer 402 wraps around the conductive body 404 and is disposed along a lower surface of the conductive body 404. The conductive body 404 may, for example, be or comprise copper, aluminum, tungsten, or any combination of the foregoing. The diffusion barrier layer 402 may, for example, be or comprise titanium, tantalum, titanium nitride, tantalum nitride, or any combination of the foregoing. In some embodiments, the diffusion barrier layer 402 and the conductive structures 108 comprise a first material (e.g., titanium nitride, tantalum nitride, etc.).

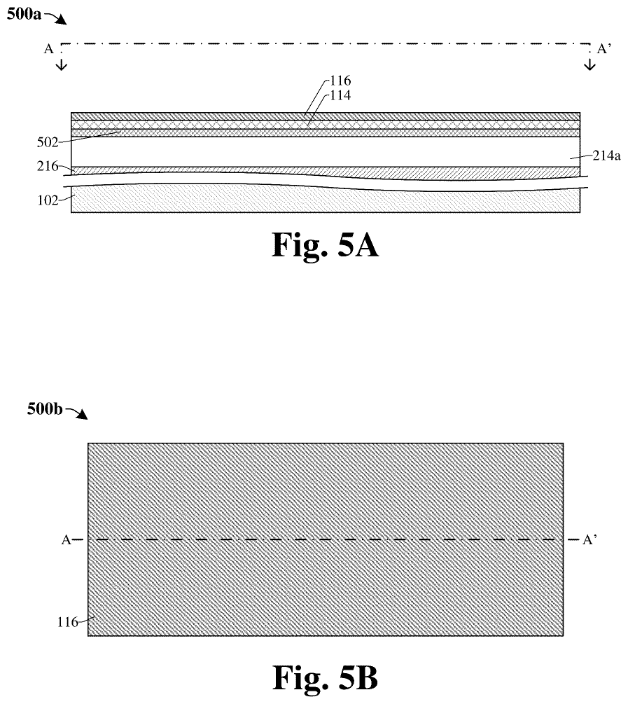

FIGS. 5A-5B through 13A-13B illustrate various views of some embodiments of a method for forming an integrated chip having a resistor structure including a capping structure overlying a TFR layer. Figures with a suffix of “A” illustrate a cross-sectional view of the integrated chip during various formation processes. Figures with a suffix of “B” illustrate respective top views taken along the line A-A′ of Figs. with a suffix of “A”. Although the various views shown in FIGS. 5A-5B through 13A-13B are described with reference to a method of forming the integrated chip, it will be appreciated that the structures shown in FIGS. 5A-5B through 13A-13B are not limited to the method of formation but rather may stand alone separate of the method.

As shown in cross-sectional view 500a and top view 500b of FIGS. 5A and 5B, a semiconductor substrate 102 is provided and a dielectric protection layer 216, a first dielectric layer 214a, a TFR film 502, a first capping layer 114, and a second capping layer 116 are formed over the semiconductor substrate 102. The semiconductor substrate 102 may, for example, be or comprise silicon, germanium, silicon germanium, epitaxial silicon, a silicon-on-insulator (SOI) substrate, some other suitable semiconductor material, or the like. The dielectric protection layer 216, the first dielectric layer 214a, the TFR film 502, the first capping layer 114, and the second capping layer 116 may be formed over the semiconductor substrate 102 by a corresponding deposition process such as, for example, chemical vapor deposition (CVD), physical vapor deposition (PVD), atomic layer deposition (ALD), or some other suitable growth or deposition process. In some embodiments, the TFR film 502, the first capping layer 114, and the second capping layer 116 are respectively formed by an individual CVD process.

The TFR film 502 may, for example, be or comprise silicon chromium, nickel chromium, or the like. In some embodiments, the TFR film 502 is formed to a thickness within a range of about 40 to 70 angstroms or some other suitable value. The first capping layer 114 may, for example, be or comprise an oxide such as silicon dioxide or some other suitable dielectric material. In various embodiments, the first capping layer 114 is formed to a thickness within a range of about 100 to 200 angstroms or some other suitable value. The second capping layer 116 may, for example, be or comprise silicon nitride, silicon carbide, some other suitable dielectric material, or any combination of the foregoing. In some embodiments, the second capping layer 116 is formed to a thickness within a range of about 100 to 200 angstroms or some other suitable value.

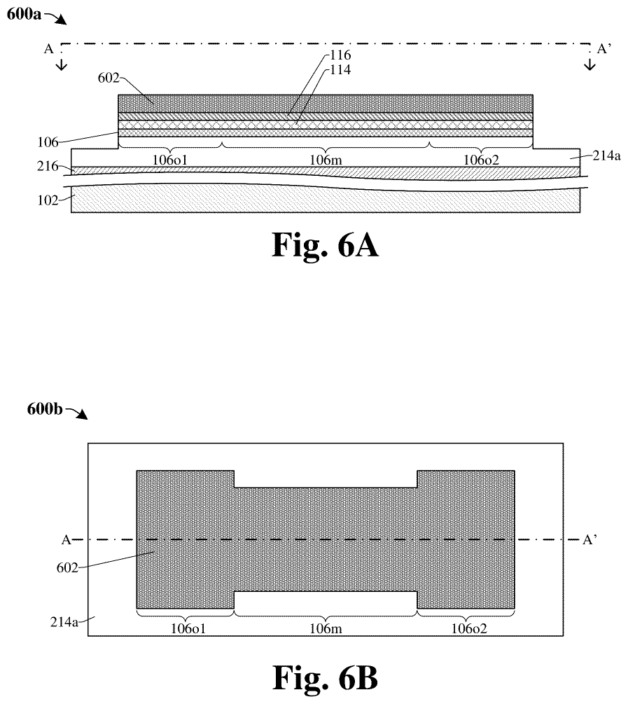

As shown in cross-sectional view 600a and top view 600b of FIGS. 6A and 6B, a first patterning process is performed on the first dielectric layer 214a, the TFR film (502 of FIG. 5A), the first capping layer 114, and the second capping layer 116, thereby defining and/or forming a TFR layer 106. The TFR layer 106 comprises a middle region 106m continuously extending between a pair of outer regions 10601, 10602, where a width of the middle region 106m is smaller than a width of the outer regions 10601, 10602. In some embodiments, the first patterning process includes forming a first masking layer 602 over the second capping layer 116 and performing a first etch process (e.g., a dry etch such as a plasma etch, a reactive-ion etch, etc.) according to the first masking layer 602. In various embodiments, the first masking layer 602 is removed during the first patterning process or after the first patterning process by a removal process (e.g., a photoresist stripping process, ash removal process, etc.) (not shown). In some embodiments, the first etch process includes exposing unmasked regions of the first dielectric layer 214a, the TFR film (502 of FIG. 5A), the first capping layer 114, and the second capping layer 116 to a first dry etchant (e.g., a carbon-based etchant such as carbon tetrafluoride).

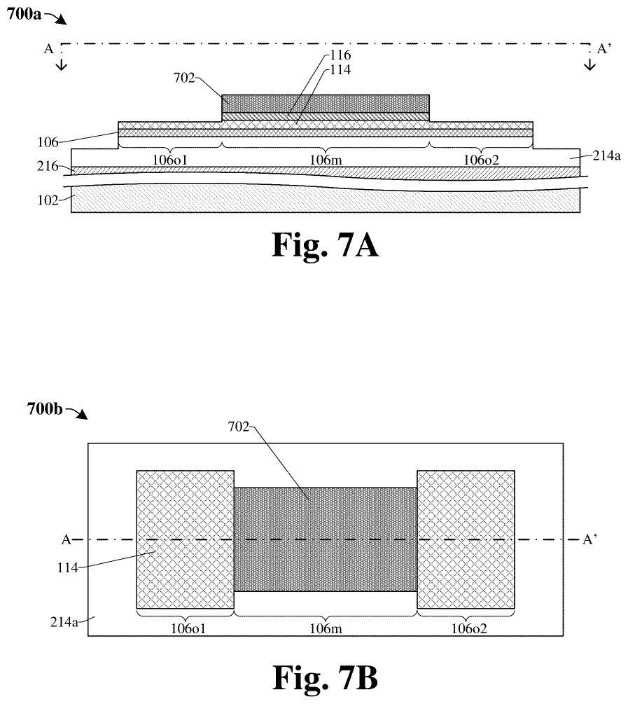

As shown in cross-sectional view 700a and top view 700b of FIGS. 7A and 7B, a second patterning process is performed on the second capping layer 116. In some embodiments the second patterning process includes forming a second masking layer 702 over the second capping layer 116 and performing a second etch process (e.g., a dry etch such as a plasma etch, a reactive-ion etch, etc.) according to the second masking layer 702. In various embodiments, the second masking layer 702 is removed during the second patterning process or after the second patterning process by a removal process (e.g., a photoresist stripping process, ash removal process, etc.) (not shown). In further embodiments, the second etch process over etches into the first capping layer 114, thereby reducing a thickness of the first capping layer 114 in a region offset from the second masking layer 702. In yet further embodiments, the second etch process includes exposing the second capping layer 116 to a second dry etchant (e.g., Difluoromethane and/or oxygen). In various embodiments, the second capping layer 116 is etched at a higher rate than the first capping layer 114 during the second patterning process.

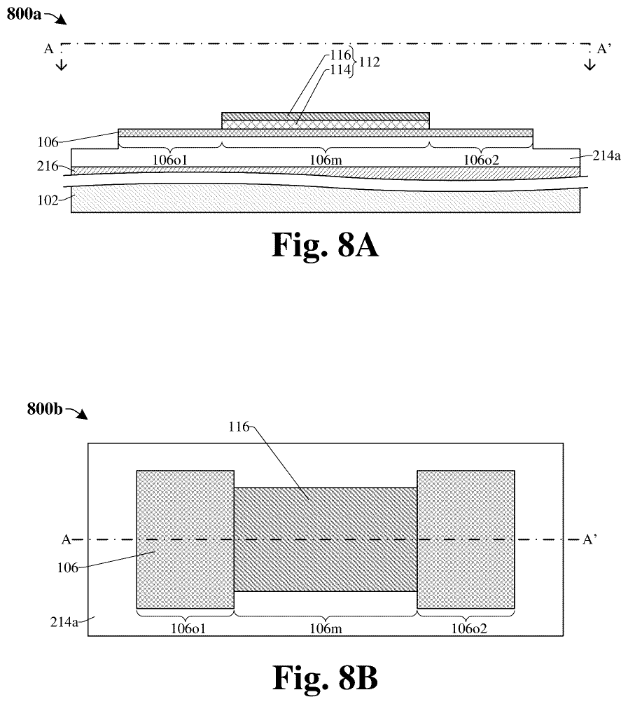

As shown in cross-sectional view 800a and top view 800b of FIGS. 8A and 8B, a third etch process is performed on the first capping layer 114, thereby defining and/or forming a capping structure 112 over the middle region 106m of the TFR layer 106. The capping structure 112 includes the first capping layer 114 and the second capping layer 116. In various embodiments, the third etch process is a wet etch process that includes exposing the first capping layer 114 and/or exposed regions of the TFR layer 106 to a first wet etchant (e.g., dilute hydrofluoric acid). In some embodiments, the second capping layer 116 is configured as a masking layer (e.g., a hard mask layer) during the third etch process.

During the third etch process the first capping layer 114 is etched at a first etching rate and the TFR layer 106 is etched at a second etching rate less than the first etching rate. In some embodiments, the first etching rate of the first capping layer 114 is about 5,000 times greater than the second etching rate of the TFR layer 106 during the third etch process. As a result, a reduction of a thickness of the TFR layer 106 is substantially minimized such that the TFR layer 106 and other TFR layers (not shown) disposed across the semiconductor substrate 102 maintain a uniform thickness during and/or after the third etch process. In some embodiments, the first etching rate of the first capping layer 114 is, for example, about 492 angstroms per a minute (A/min) and the second etching rate of the TFR layer 106 is, for example, about 0.0225 A/min during the third etch process.

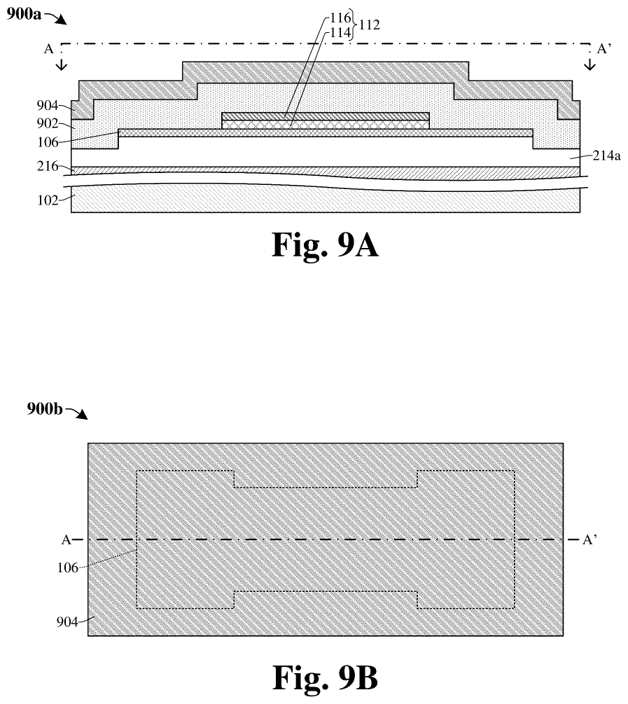

As shown in cross-sectional view 900a and top view 900b of FIGS. 9A and 9B, a conductive layer 902 and an etch stop film 904 are formed over the semiconductor substrate 102. The conductive layer 902 may be formed over the semiconductor substrate 102 by, for example, CVD, PVD, ALD, or some other suitable growth or fabrication process. The conductive layer 902 may, for example, be or comprise titanium nitride, tantalum nitride, titanium, tantalum, some other conductive material, or any combination of the foregoing. In some embodiments, the conductive layer 902 is formed to a thickness of about 500 to 1,000 angstroms or some other suitable value. The etch stop film 904 may be formed over the conductive layer 902 by, for example, CVD, PVD, ALD, or some other suitable growth or fabrication process. The etch stop film 904 may, for example, be or comprise silicon nitride, silicon carbide, silicon oxynitride, some other dielectric material, or any combination of the foregoing. In some embodiments, the etch stop film 904 is formed to a thickness of about 300 to 500 angstroms or some other suitable value. In various embodiments, the thickness of the conductive layer 902 is greater than the thickness of the etch stop film 904. In further embodiments, the conductive layer 902 and the etch stop film 904 are respectively formed by an individual CVD process.

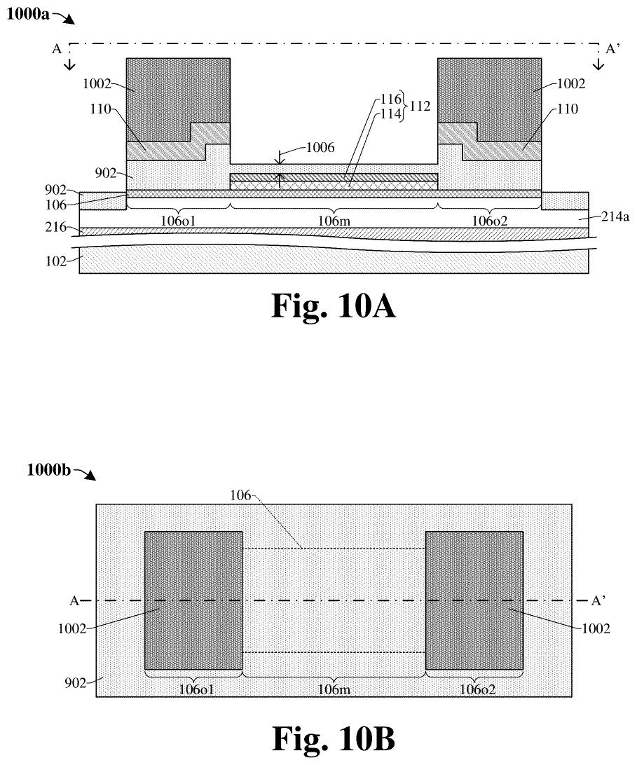

As shown in cross-sectional view 1000a and top view 1000b of FIGS. 10A and 10B, a third patterning process is performed on the etch stop film (904 of FIGS. 9A and 9B) and the conductive layer 902, thereby defining and/or forming an etch stop layer 110 over the outer regions 10601, 10602 of the TFR layer 106. In some embodiments, the third patterning process includes forming a third masking layer 1002 over the semiconductor substrate 102 and performing a fourth etch process (e.g., a dry etch such as a plasma etch, a reactive-ion etch, etc.) according to the third masking layer 1002. In various embodiments, the third masking layer 1002 is removed during the third patterning process or after the third patterning process by a removal process (e.g., a photoresist stripping process, ash removal process, etc.) (not shown). In further embodiments, the fourth etch process reduces a thickness of the conductive layer 902 over the middle region 106m of the TFR layer 106 to a thickness 1006 that is about 200 angstroms or within a range of about 100 to 200 angstroms. By virtue of at least a portion of the conductive layer 902 remaining over the middle region 106m of the TFR layer 106 after the third patterning process, damage to the TFR layer 106 from the fourth etch process is reduced and/or a reduction of the thickness of the TFR layer 106 is mitigated or prevented during the fourth etch process.

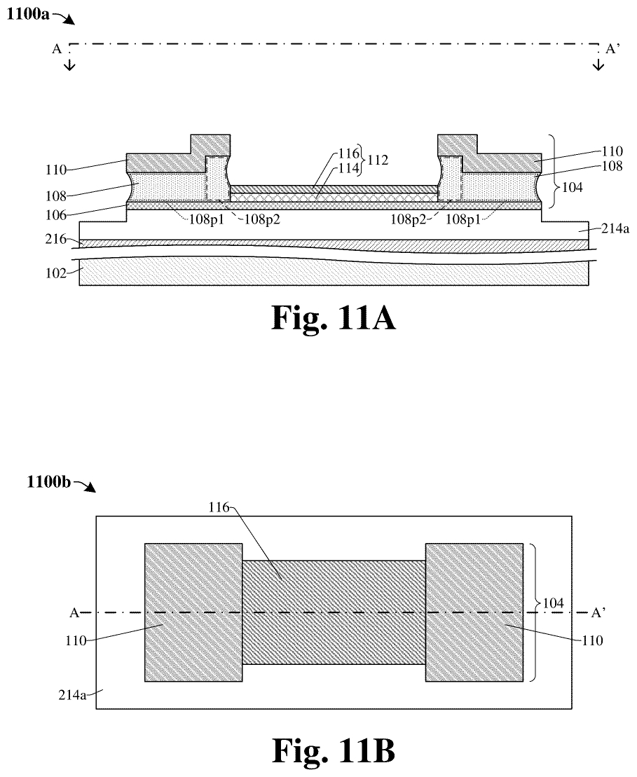

As shown in cross-sectional view 1100a and top view 1100b of FIGS. 11A and 11B, a fifth etch process is performed on the conductive layer (902 of FIG. 10A), thereby defining and/or forming a pair of conductive structures 108 on opposing sides of the TFR layer 106 and a resistor structure 104. In some embodiments, a process for forming the pair of conductive structures 108 includes the processing steps illustrated and/or described in FIGS. 9A-9B through 11A-11B. In various embodiments, the fifth etch process is a wet etch process that includes exposing the conductive layer (902 of FIG. 10A) to a second wet etchant (e.g., hydrogen peroxide). In various embodiments, the fifth etch process is different from the third etch process of FIGS. 8A and 8B. The conductive structures 108 respectively comprise a first portion 108p1 adjacent to a second portion 108p2, where a height of the first portion 108p1 is less than a height of the second portion 108p2. In some embodiments, the first and second portions 108p1, 108p2 respectively comprise at least one curved sidewall segment as a result of the second wet etchant removing lateral portions of the conductive structures 108. In yet further embodiments, the fifth etch process is a dry etch process (e.g., a blanket dry etch, a plasma etch, a reactive-ion etch, etc.). In such embodiments, outer sidewalls of the conductive structures 108 are straight (e.g., as illustrated and/or described in FIG. 4A). In some embodiments, the etch stop layer 110 is configured as a masking layer (e.g., a hard mask layer) during the fifth etch process.

By virtue of the capping structure 112 overlying the TFR layer 106 during the fifth etch process, damage to and/or a reduction of the thickness of the TFR layer 106 during the fifth etch process is mitigated and/or prevented. This, in part, facilitates the TFR layer 106 maintaining a low TTV and mitigates a non-uniform removal of other TFR layers (not shown) across the semiconductor substrate 102. As a result, a uniformity of a resistance of the resistor structure 104 and other resistor structures (not shown) disposed across the semiconductor substrate 102 is increased, thereby increasing an overall performance and device yield of the integrated chip. In yet further embodiments, during the fifth etch process the conductive layer (902 of FIG. 10A) is etched more quickly than the etch stop layer 110 and/or layers of the capping structure 112.

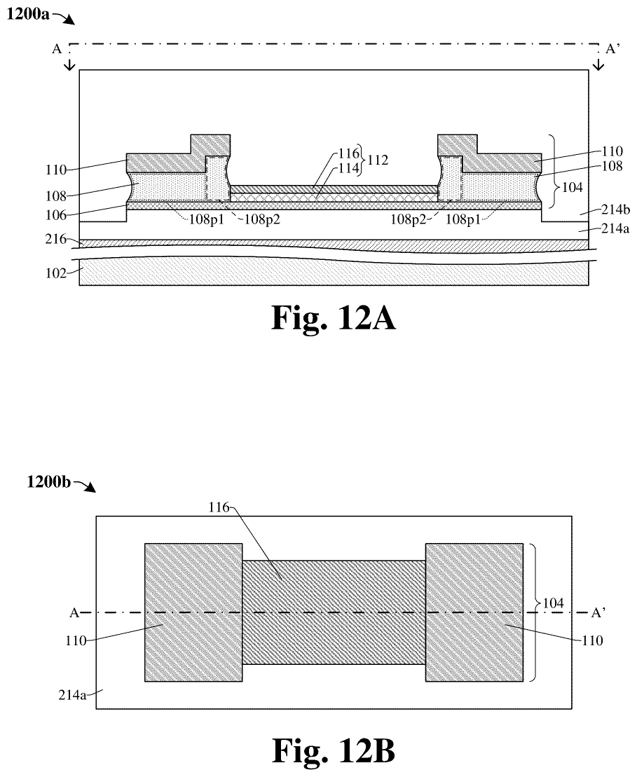

As shown in cross-sectional view 1200a and top view 1200b of FIGS. 12A and 12B, a second dielectric layer 214b is formed over the resistor structure 104. It will be appreciated that the second dielectric layer 214b is omitted from the top view 1200b of FIG. 12B for ease of illustration. The second dielectric layer 214b may, for example, be formed over the resistor structure 104 by CVD, PVD, ALD, or some other suitable growth or deposition process. In some embodiments, the first dielectric layer 214a and the second dielectric layer 214b comprise a same material.

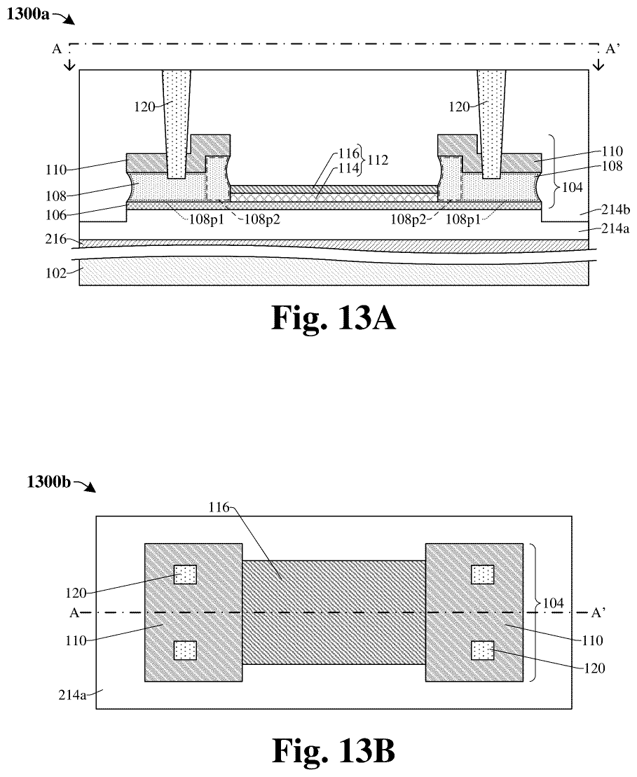

As shown in cross-sectional view 1300a and top view 1300b of FIGS. 13A and 13B, a plurality of conductive vias 120 are formed in the second dielectric layer 214b and over the conductive structures 108. It will be appreciated that the second dielectric layer 214b is omitted from the top view 1300b of FIG. 13B for ease of illustration. In some embodiments, a process for forming the plurality of conductive vias 120 includes: patterning the second dielectric layer 214b to form a plurality of openings over the conductive structures 108; depositing (e.g., by CVD, PVD, ALD, electroplating, electroless plating, etc.) one or more conductive materials (e.g., copper, aluminum, ruthenium, titanium, titanium nitride, tantalum nitride, etc.) within the openings; and performing a planarization process (e.g., a chemical mechanical planarization (CMP) process) on the one or more conductive materials.

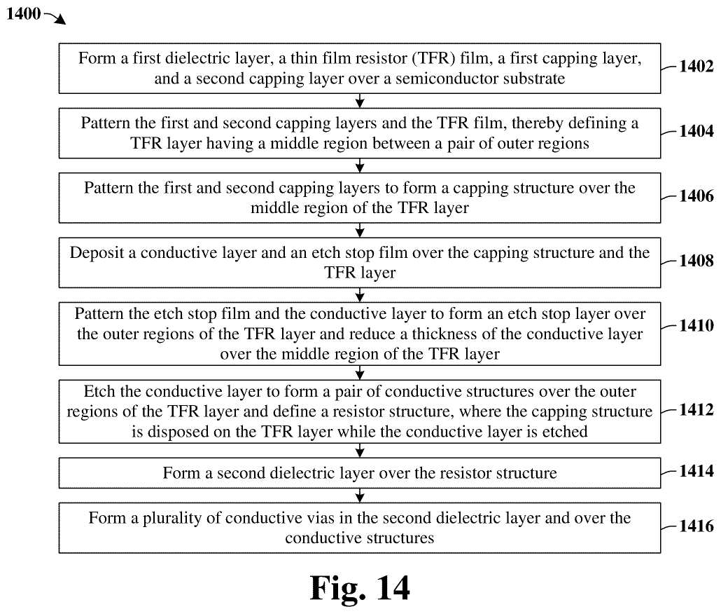

FIG. 14 illustrates a flowchart of some embodiments of a method 1400 for forming an integrated chip having a resistor structure including a capping structure overlying a TFR layer. Although the method 1400 is illustrated and/or described as a series of acts of events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 1402, a first dielectric layer, a TFR film, a first capping layer, and a second capping layer are formed over a semiconductor substrate. FIGS. 5A and 5B illustrate various views of some embodiments corresponding to act 1402.

At act 1404, the first and second capping layers and the TFR film are patterned, thereby defining a TFR layer having a middle region between a pair of outer regions. FIGS. 6A and 6B illustrate various views of some embodiments corresponding to act 1404.

At act 1406, the first and second capping layers are patterned to form a capping structure over the middle region of the TFR layer. FIGS. 7A, 7B, 8A, and 8B illustrate various views of some embodiments corresponding to act 1406.

At act 1408, a conductive layer and an etch stop film are deposited over the capping structure and the TFR layer. FIGS. 9A and 9B illustrate various views of some embodiments corresponding to act 1408.

At act 1410, the etch stop film and the conductive layer are patterned to form an etch stop layer over the outer regions of the TFR layer and reduce a thickness of the conductive layer over the middle region of the TFR layer. FIGS. 10A and 10B illustrate various views of some embodiments corresponding to act 1410.

At act 1412, the conductive layer is etched to form a pair of conductive structures over the outer regions of the TFR layer and define a resistor structure, where the capping structure is disposed on the TFR layer while the conductive layer is etched. FIGS. 11A and 11B illustrate various views of some embodiments corresponding to act 1412.

At act 1414, a second dielectric layer is formed over the resistor structure. FIGS. 12A and 12B illustrate various views of some embodiments corresponding to act 1414.

At act 1416, a plurality of conductive vias are formed in the second dielectric layer and over the conductive structures. FIGS. 13A and 13B illustrate various views of some embodiments corresponding to act 1416.

Accordingly, in some embodiments, the present disclosure relates to a resistor structure comprising a TFR layer, a pair of conductive structures disposed on opposing sides of the TFR layer, and a capping structure on the TFR layer between the pair of conductive structures.

In some embodiments, the present application provides an integrated chip, including: a thin film resistor (TFR) layer overlying a semiconductor substrate; a first conductive structure disposed on an outer region of the TFR layer, wherein the first conductive structure comprises a lateral portion adjacent to a vertical portion, wherein a height of the vertical portion is greater than a height of the lateral portion; and a capping structure disposed on a middle region of the TFR layer and abutting the vertical portion of the first conductive structure. In an embodiment, the capping structure directly contacts a first sidewall of the vertical portion. In an embodiment, the first sidewall of the vertical portion comprises a curved segment over a straight segment. In an embodiment, a second sidewall of the lateral portion is curved. In an embodiment, a height of the second sidewall is greater than a height of the straight segment of the first sidewall. In an embodiment the integrated chip further includes: an etch stop layer disposed on the first conductive structure, wherein the etch stop layer extends along a top surface of the lateral portion and along a sidewall and top surface of the vertical portion; and a conductive via extending through the etch stop layer to the first conductive structure. In an embodiment, a width of the first conductive structure is greater than a width of the middle region of the TFR layer. In an embodiment, a first sidewall of the vertical portion is straight.

In some embodiments, the present application provides an integrated chip, including: a first dielectric layer overlying a semiconductor substrate; a resistor structure overlying the first dielectric layer, wherein the resistor structure comprises a thin film resistor (TFR) layer and a pair of conductive structure, wherein the TFR layer comprises a middle region extending between a pair of outer regions, wherein the conductive structures overlie the outer regions; a second dielectric layer overlying and extending around the TFR layer; and a capping structure disposed on the middle region of the TFR layer and extending between the conductive structures, wherein a lower surface of the second dielectric layer is vertically spaced from the TFR layer by the capping structure. In an embodiment, a bottom surface of the second dielectric layer is disposed below a top surface of the TFR layer. In an embodiment, the capping structure comprises a first capping layer on the TFR layer and a second capping layer on the first capping layer, wherein the first capping layer comprises a first material and the second capping layer comprises a second material different from the first material. In an embodiment, the second dielectric layer comprises the first material. In an embodiment, thicknesses of the first and second capping layers are each greater than a thickness of the TFR layer. In an embodiment, the conductive structures respectively comprise a first portion adjacent to a second portion, wherein the second portion is spaced between the capping structure and the first portion, wherein a height of the first portion is greater than a height of the capping structure. In an embodiment, a width of the capping structure is less than a width of the pair of conductive structures, wherein a length of the capping structure is greater than a length of a first conductive structure in the pair of conductive structures.

In some embodiments, the present application provides a method for forming an integrated chip, including: forming a thin film resistor (TFR) layer over a semiconductor substrate; forming a capping structure over a middle region of the TFR layer; depositing a conductive layer and an etch stop layer over the TFR layer and the capping structure; and performing a first patterning process on the conductive layer and the etch stop layer, thereby defining a pair of conductive structures on outer regions of the TFR layer, wherein the capping structure is disposed on the TFR layer during the first patterning process. In an embodiment, the first patterning process includes: performing a first etch on the conductive layer and the etch stop layer, wherein the first etch reduces a thickness of a portion of the conductive layer over the middle region of the TFR layer; and performing a second etch on the conductive layer to remove the portion of the conductive layer over the middle region of the TFR layer, wherein the first etch is different from the second etch. In an embodiment, the first etch is a dry etch and the second etch is a wet etch. In an embodiment, forming the capping structure includes: depositing a first capping layer and a second capping layer on the TFR layer; performing a dry etch on the second capping layer; and performing a wet etch on the first capping layer, wherein a first etching rate of the first capping layer is greater than a second etching rate of the TFR layer during the wet etch. In an embodiment, the method further comprises: depositing an upper dielectric layer over the TFR layer, wherein the upper dielectric layer contacts outer sidewalls of the TFR layer, and wherein the capping structure is disposed directly between a lower surface of the upper dielectric layer and a top surface of the TFR layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a thin film resistor (TFR) layer overlying a semiconductor substrate;
a first conductive structure disposed on an outer region of the TFR layer, wherein the first conductive structure comprises a lateral portion adjacent to a vertical portion, wherein a height of the vertical portion is greater than a height of the lateral portion; and
a capping structure disposed on a middle region of the TFR layer and abutting the vertical portion of the first conductive structure.

2. The integrated chip of claim 1, wherein the capping structure directly contacts a first sidewall of the vertical portion.

3. The integrated chip of claim 2, wherein the first sidewall of the vertical portion comprises a curved segment over a straight segment.

4. The integrated chip of claim 3, wherein a second sidewall of the lateral portion is curved.

5. The integrated chip of claim 4, wherein a height of the second sidewall is greater than a height of the straight segment of the first sidewall.

6. The integrated chip of claim 1, further comprising:
an etch stop layer disposed on the first conductive structure, wherein the etch stop layer extends along a top surface of the lateral portion and along a sidewall and top surface of the vertical portion; and
a conductive via extending through the etch stop layer to the first conductive structure.

7. The integrated chip of claim 1, wherein a width of the first conductive structure is greater than a width of the middle region of the TFR layer.

8. The integrated chip of claim 1, wherein a first sidewall of the vertical portion is straight.

9. An integrated chip, comprising:
a first dielectric layer overlying a semiconductor substrate;
a resistor structure overlying the first dielectric layer, wherein the resistor structure comprises a thin film resistor (TFR) layer and a pair of conductive structure, wherein the TFR layer comprises a middle region extending between a pair of outer regions, wherein the conductive structures overlie the outer regions;
a second dielectric layer overlying and extending around the TFR layer; and
a capping structure disposed on the middle region of the TFR layer and extending between the conductive structures, wherein a lower surface of the second dielectric layer is vertically spaced from the TFR layer by the capping structure.

10. The integrated chip of claim 9, wherein a bottom surface of the second dielectric layer is disposed below a top surface of the TFR layer.

11. The integrated chip of claim 9, wherein the capping structure comprises a first capping layer on the TFR layer and a second capping layer on the first capping layer, wherein the first capping layer comprises a first material and the second capping layer comprises a second material different from the first material.

12. The integrated chip of claim 11, wherein the second dielectric layer comprises the first material.

13. The integrated chip of claim 11, wherein thicknesses of the first and second capping layers are each greater than a thickness of the TFR layer.

14. The integrated chip of claim 9, wherein the conductive structures respectively comprise a first portion adjacent to a second portion, wherein the second portion is spaced between the capping structure and the first portion, wherein a height of the first portion is greater than a height of the capping structure.

15. The integrated chip of claim 9, wherein a width of the capping structure is less than a width of the pair of conductive structures, wherein a length of the capping structure is greater than a length of a first conductive structure in the pair of conductive structures.

16. A method of forming an integrated chip, comprising:
forming a thin film resistor (TFR) layer over a semiconductor substrate;
forming a capping structure over a middle region of the TFR layer;
depositing a conductive layer and an etch stop layer over the TFR layer and the capping structure; and
performing a first patterning process on the conductive layer and the etch stop layer, thereby defining a pair of conductive structures on outer regions of the TFR layer, wherein the capping structure is disposed on the TFR layer during the first patterning process.

17. The method of claim 16, wherein the first patterning process includes:
performing a first etch on the conductive layer and the etch stop layer, wherein the first etch reduces a thickness of a portion of the conductive layer over the middle region of the TFR layer; and
performing a second etch on the conductive layer to remove the portion of the conductive layer over the middle region of the TFR layer, wherein the first etch is different from the second etch.

18. The method of claim 17, wherein the first etch is a dry etch and the second etch is a wet etch.

19. The method of claim 16, wherein forming the capping structure includes:
depositing a first capping layer and a second capping layer on the TFR layer;
performing a dry etch on the second capping layer; and
performing a wet etch on the first capping layer, wherein a first etching rate of the first capping layer is greater than a second etching rate of the TFR layer during the wet etch.

20. The method of claim 16, further comprising:
depositing an upper dielectric layer over the TFR layer, wherein the upper dielectric layer contacts outer sidewalls of the TFR layer, and wherein the capping structure is disposed directly between a lower surface of the upper dielectric layer and a top surface of the TFR layer.
